(19) United States
(12) Patent Application Publication
(10) Pub. No.: US 2025/0323161 A1
(43) Pub. Date: Oct. 16, 2025

(54) CONDUCTIVE FEATURES OF SEMICONDUCTOR DEVICE AND METHOD OF FORMING SAME

(71) Applicant: Taiwan Semiconductor Manufacturing Co., Ltd., Hsinchu (TW)

(72) Inventors: Ming-Chou Chiang, Hsinchu County (TW); Chih-Yi Chang, New Taipei City (TW); Hung-Yi Huang, Hsinchu (TW)

(21) Appl. No.: 19/247,185

(22) Filed: Jun. 24, 2025

Related U.S. Application Data
(63) Continuation of application No. 18/529,948, filed on Dec. 5, 2023.
(60) Provisional application No. 63/519,371, filed on Aug. 14, 2023.

(51) Int. Cl. H01L 23/528; H01L 21/768; H10D 62/10

(52) U.S. Cl. CPC H01L 23/5286; H01L 21/76828; H01L 21/76831; H10D 62/115

(57) ABSTRACT

A method includes forming a conductive layer over a first dielectric layer; etching a recess in the conductive layer, wherein the recess exposes a top surface of the first dielectric layer; selectively depositing a capping layer on exposed sidewalls of the conductive layer within the recess; depositing a liner on the capping layer; forming a sacrificial material in the recess; and forming a second dielectric layer on the sacrificial material and on sidewalls of the recess; and after forming the second dielectric layer, performing a thermal process to remove the sacrificial material.

### PRIORITY CLAIM AND CROSS-REFERENCE

This application is a continuation of U.S. patent application Ser. No. 18/529,948, filed on Dec. 5, 2023, which claims the benefit of U.S. Provisional Application No. 63/519,371, filed on Aug. 14, 2023, each application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6, 7, 8, 9, 10, 11, and 12 illustrate cross-sectional views of intermediate steps in the formation of conductive features, in accordance with some embodiments.

FIG. 13 illustrates a cross-sectional view of an air gap, in accordance with some embodiments.

FIG. 14 illustrates a cross-sectional view of an intermediate step in the formation of additional conductive features, in accordance with some embodiments.

FIG. 15 illustrates a cross-sectional view of conductive features, in accordance with some embodiments.

FIG. 16 illustrates a cross-sectional view of conductive features, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments described herein allow for the formation of low-resistance conductive features such as vias, lines, or the like. The techniques described herein may form conductive features as part of a Front-End-of-Line (FEOL) process, a Middle-End-of-Line (MEOL) process, and/or a Back-End-of-Line (BEOL) process. In some embodiments, a capping layer is selectively deposited on sidewalls of the conductive features. The capping layer protects sidewalls of the conductive features and reduces or prevents deformation of the sidewalls during subsequent process steps. Additionally, some embodiments describe isolating conductive features using air gaps, which can reduce capacitance and improve performance.

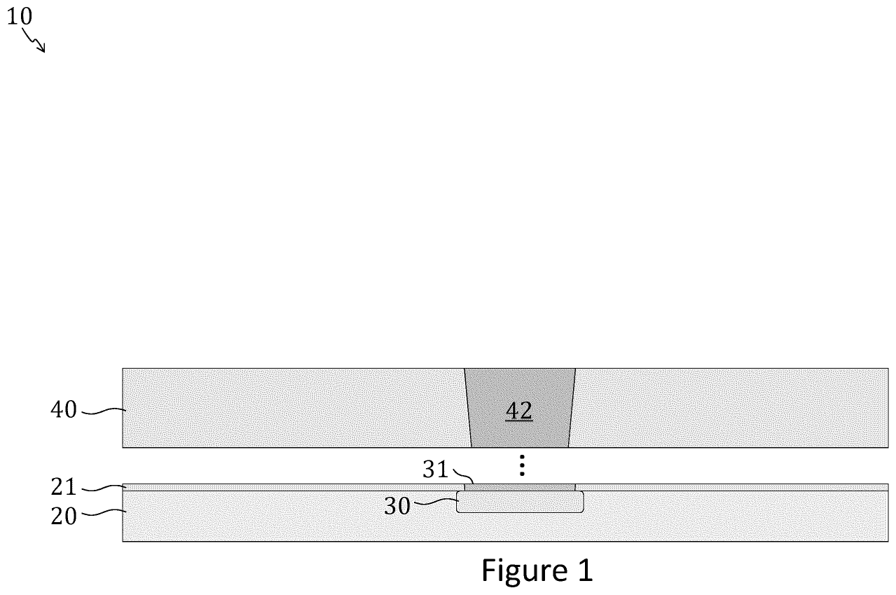

FIG. 1 illustrates a cross-sectional view of wafer 10, in accordance with some embodiments. In accordance with some embodiments of the present disclosure, wafer 10 is or comprises a device wafer including active devices and possibly passive devices, which are represented as integrated circuit devices 30. Wafer 10 may include a plurality of integrated circuit dies therein, with a portion of one of the integrated circuit dies being illustrated. The wafer 10 may include different device regions that are singulated in subsequent steps to form a plurality of integrated circuit dies. The wafer 10 may be processed according to applicable manufacturing processes to form integrated circuits, and may be packaged in subsequent processing to form an integrated circuit package.

In some embodiments, the wafer 10 comprises a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. In accordance with alternative embodiments of the present disclosure, wafer 10 is an interposer wafer, which is free from active devices, and may or may not include passive devices.

In some embodiments, the wafer 10 includes a substrate 20. In some embodiments, the substrate 20 is a semiconductor substrate, such as silicon, doped or undoped, or an active layer of a semiconductor-on-insulator (SOI) substrate. The substrate 20 may include other semiconductor materials, such as germanium; a compound semiconductor including silicon carbide, gallium arsenic, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The substrate 20 has an active surface (e.g., the surface facing upwards in FIG. 1), sometimes called a front side, and an inactive surface (e.g., the surface facing downwards in FIG. 1), sometimes called a back side. In other embodiments, the substrate 20 is a material other than a semiconductor material.

Devices 30 may be formed at the front surface of the substrate 12, represented in FIG. 1 by integrated circuit device 30. The devices 30 may be active devices and/or passive devices. A wide variety of devices 30 such as transistors (e.g., fin field-effect transistors (FinFETs), planar FETs, nanostructure (e.g., nanosheet, nanowire, gate-all-around, or the like) field-effect transistors (NSFETs), or the like), diodes, capacitors, resistors, combinations of these, and the like may be used to generate the structural and functional requirements of the design for the wafer 10. The devices 30 may be formed using any suitable methods. In accordance with alternative embodiments, wafer 10 is used for forming interposers (which are free from active devices), and substrate 20 may be a semiconductor substrate or a dielectric substrate.

Conductive plugs 31 may be formed that physically and electrically couple the devices 30. For example, a dielectric layer 21, such as an Inter-Metal Dielectric (IMD) layer, may be formed over the substrate 20, and then the conductive plugs 31 may be formed extending through the dielectric layer 21 to contact the devices 30. For example, when the devices 30 are transistors, the conductive plugs 31 may couple the gates and source/drain regions of the transistors. Source/drain region(s) may refer to a source or a drain, individually or collectively dependent upon the context. Other types of conductive plugs 31 are possible. The conductive plugs 31 may be formed of tungsten, cobalt, nickel, copper, silver, gold, aluminum, ruthenium, cobalt, molybdenum, the like, or combinations thereof. This is an illustrative example, and other conductive plugs 31 are possible.

A plurality of interconnections may be formed over the substrate 20 and may interconnect the devices 30. For example, the interconnections may be electrically coupled to the conductive plugs 31. The plurality of interconnections may comprise, for example, a plurality of conductive features formed in a plurality of dielectric layers. The conductive features may include, for example, conductive lines, vias, contacts, metallization patterns, redistribution layers, or the like. In some embodiments, the interconnections may be formed of alternating layers of dielectric material (e.g., low-k dielectric material) and conductive material with vias interconnecting the layers of conductive material.

The dielectric layers may be, for example, Inter-Layer Dielectric (ILD) layers and/or IMD layers, in some embodiments. In some embodiments, the dielectric layers may be formed of materials such as silicon oxide, silicon nitride, Phospho-Silicate Glass (PSG), Boro-Silicate Glass (BSG), Boron-Doped Phospho-Silicate Glass (BPSG), undoped Silicate Glass (USG), or the like. The dielectric layers may be formed using a suitable deposition technique, such as Plasma Enhanced Chemical Vapor Deposition (PECVD), Low Pressure Chemical Vapor Deposition (LPCVD), or the like. Other materials or techniques are possible. The conductive features may be formed through any suitable process, such as deposition, damascene, dual damascene, or the like. The conductive features may be formed of one or more conductive materials similar to those described above for the conductive plugs 31. The interconnections may be formed as part of a Front-End-of-Line (FEOL) process and/or as part of a Back-End-of-Line (BEOL) process.

As an example, FIG. 1 illustrates a conductive feature 42 formed in a dielectric layer 40. The conductive feature 42 may be, for example, a conductive line, via, or contact. The dielectric layer 40 may be, for example, an ILD layer. For example, the conductive feature 42 may comprise molybdenum and the dielectric layer 40 may comprise silicon oxide, though other materials are possible. As indicated in FIG. 1, one or more interconnections (e.g., conductive features formed in dielectric layers) may be formed between the conductive feature 42 and the contact plug 31. In other embodiments, the conductive feature 42 may be formed physically and electrically contacting the conductive plug 31. The conductive feature 42 shown in FIG. 1 is an example, and in other cases more than one conductive feature 42 may be formed in the dielectric layer 40 or the conductive feature 42 may have another shape, size, arrangement, or composition than the example described herein.

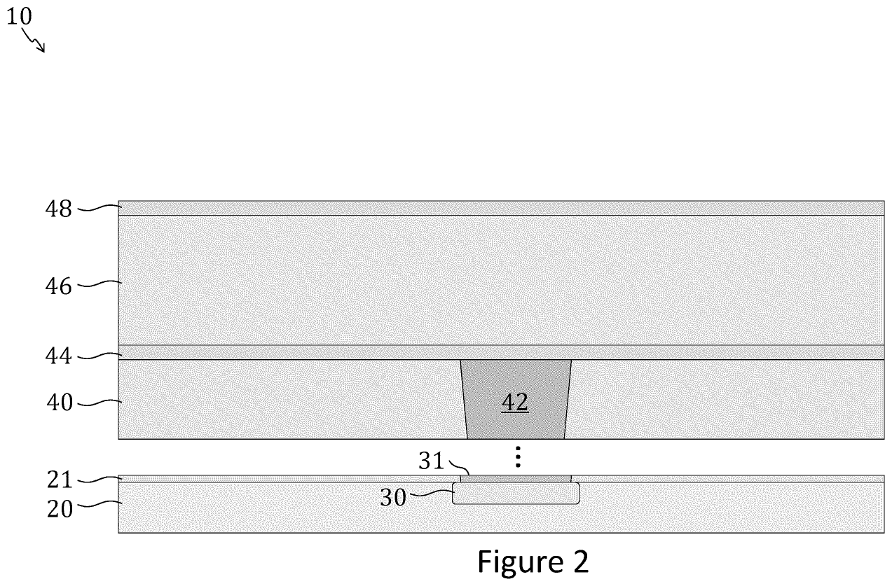

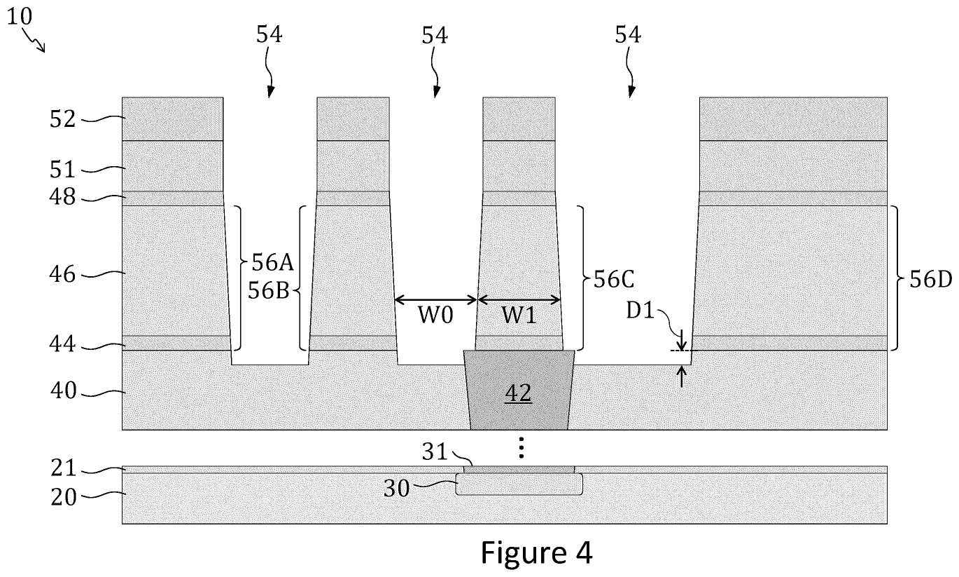

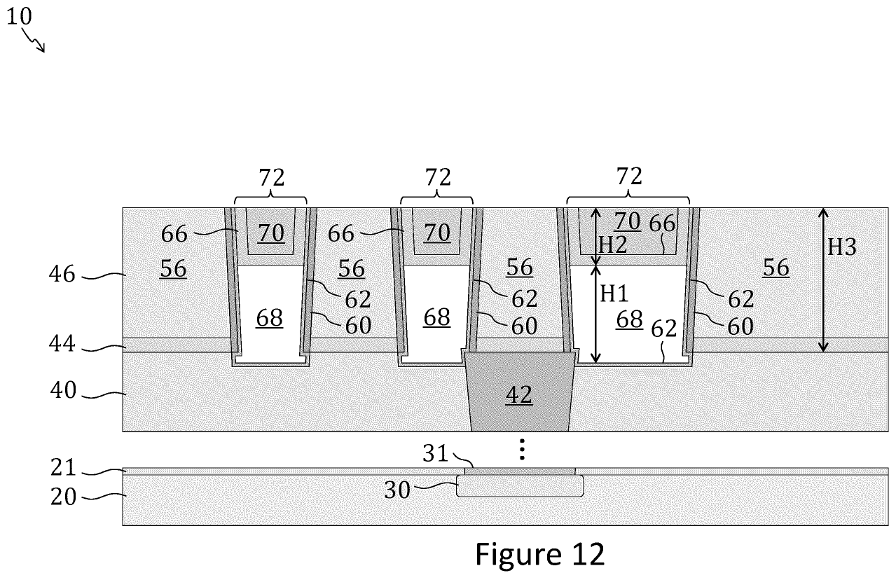

FIGS. 2 through 12 illustrate cross-sectional views of intermediate steps in the formation of conductive features 56 (see conductive features 56 of FIG. 12), in accordance with some embodiments. The conductive features 56 are conductive lines or vias formed over the dielectric layer 40, which may physically and electrical contact the conductive feature 42 (see conductive feature 56C in FIG. 4). The conductive features 56 are separated by air gaps 68 (see FIG. 12), described in greater detail below.

In FIG. 2, a conductive layer 46 is formed over the dielectric layer 40 and conductive feature 42, in accordance with some embodiments. The conductive features 56 are subsequently formed from the conductive layers 46. In some embodiments, a barrier layer 44 is first deposited on the dielectric layer 40 and the conductive feature 42. The barrier layer 44 may comprise one or more materials such as titanium, titanium nitride, titanium oxide, tantalum, tantalum nitride, tantalum oxide, titanium tungsten, the like, or a combination thereof. Other materials are possible. The barrier layer 44 may be deposited using a suitable technique, such as PECVD, PVD, ALD, or the like. In some cases, the barrier layer 44 may be considered an adhesion layer or an etch stop layer. The barrier layer 44 may have a thickness in the range of about 1 nm to about 3 nm, though other thicknesses are possible.

The conductive layer 46 may then be deposited on the barrier layer 44. The conductive layer 46 may comprise one or more conductive materials such as copper, silver, gold, tungsten, aluminum, cobalt, ruthenium, molybdenum, alloys thereof, combinations thereof, or the like. For example, in some embodiments, the conductive layer 46 may comprise a conductive material having a relatively large grain sizes, such as ruthenium or the like. In some cases, a conductive material having larger grain size can have a smaller bulk resistance due to the larger grains providing fewer interfaces for electron scattering. The conductive layer 46 may be deposited using a suitable technique, such as CVD, PECVD, ALD, plating, or the like. Other materials or techniques are possible. In some embodiments, the conductive layer 46 has a thickness in the range of about 220 nm to about 260 nm, though other thicknesses are possible.

A second barrier layer 48 may then be deposited on the conductive layer 46, in some embodiments. The barrier layer 48 may be similar to the barrier layer 44, in some embodiments. For example, the barrier layer 48 may be a layer of titanium nitride having a thickness in the range of about 1 nm to about 3 nm. Other materials or thicknesses are possible. In some cases, the barrier layer 44 and the barrier layer 48 are different materials.

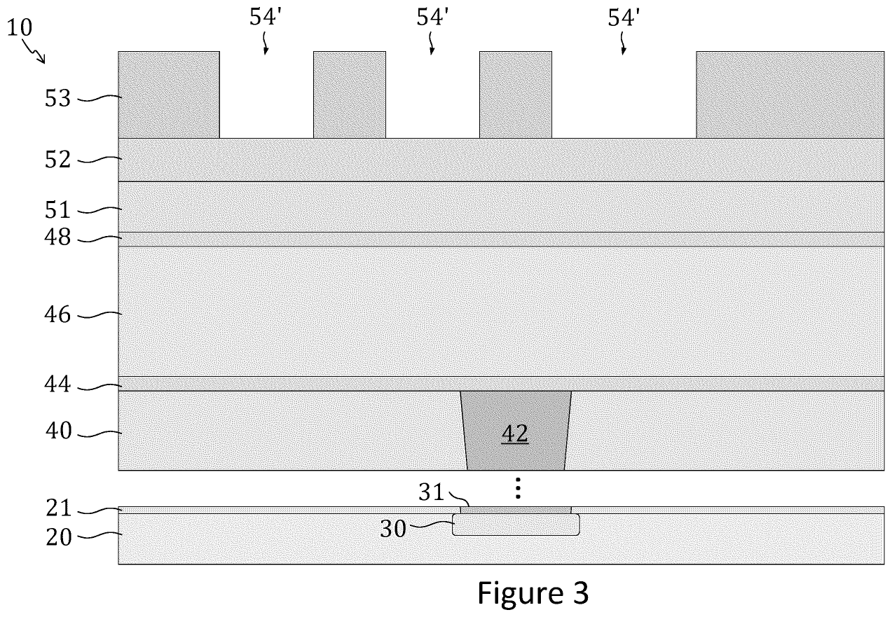

In FIG. 3, hard mask layers 51 and 52 are formed over the barrier layer 48, in accordance with some embodiments. The hard mask layer 51 may be formed of a different material than the hard mask layer 52, in some embodiments. For example, the hard mask layers 51 and 52 may be formed of different materials such that the hard mask layer 52 may be selectively etched (e.g., without significant etching of the hard mask layer 51). The hard mask layers 51 and 52 may be formed of dielectric materials such as silicon nitride, silicon oxide, silicon oxynitride, or the like. For example, in some embodiments, the hard mask layer 51 is formed of silicon nitride and the hard mask layer 52 is formed of silicon oxide. Other materials are possible. In some embodiments, the hard mask layers 51 and 52 each have a thickness in the range of about 20 nm to about 30 nm, though other thicknesses are possible. In other embodiments, only one hard mask layer or more than two hard mask layers are formed over the barrier layer 48.

Still referring to FIG. 3, a patterned photoresist 53 may be formed over the hard mask layer 52, in some embodiments. For example, a photoresist 53 may be deposited over the hard mask layer 52 and then patterned using suitable photolithography techniques to form openings 54′ in the photoresist 53. In some embodiments, the locations of the openings 54′ correspond to regions between subsequently-formed conductive features 56 (see FIG. 12). For example, the openings 54′ may correspond to subsequently-formed air gaps 68 (see FIG. 12).

In FIG. 4, one or more etching steps are performed to extend the openings 54′ and form recesses 54, in accordance with some embodiments. As shown in FIG. 4, the recesses 54 extend through the barrier layer 48, the barrier layer 44, and the conductive layer 46, and expose the dielectric layer 40. In this manner, the recesses 54 separate regions of the conductive layer 46 and the barrier layer 44 to define conductive features 56, described in greater detail below.

In some embodiments, one or more etching steps are first performed to extend the openings 54′ through the hard mask layer 52 and the hard mask layer 51. For example, an etching step may be performed to extend the openings 54′ into the hard mask layer 52 using the patterned photoresist 53 as an etching mask, forming recesses 54 in the hard mask layer 52. In some embodiments, the etching step may selectively etch the mask layer 52 and stop on the mask layer 51. An etching step may then be performed to etch the hard mask layer 51 using the hard mask layer 52 as an etching mask, extending the recesses 54 into the hard mask layer 51. The etching steps may include a wet etching process, a dry etching process, and/or a RIE process. One or more of the etching steps may be anisotropic. In other embodiments, both hard mask layers 51 and 52 may be etched using the same etching step. In some cases, the photoresist 53 may be removed during an etching step or may be removed after an etching step using, for example, an ashing process or the like. In some cases, the remaining portions of the hard mask layers 51 and 52 form a patterned hard mask (not separately labeled).

In some embodiments, the barrier layer 48, the conductive layer 46, and the barrier layer 48 are then etched using the hard mask layers 51 and 52 as an etching mask. For example, one or more etching steps may be performed to extend the recesses 54 to the dielectric layer 40. The etching steps may include a wet etching process, a dry etching process, and/or a RIE process. One or more of the etching steps may be anisotropic. For example, in some embodiments, an RIE process is performed to extend the recesses 54 through the barrier layer 44, the conductive layer 46, and the barrier layer 44. In some embodiments, the etching steps may include one or more timed etches used to extend the recesses 54 to the desired depth.

As shown in FIG. 4, the recesses 54 remove portions of the barrier layer 44 to expose surfaces of the dielectric layer 40. In some embodiments, the recesses 54 extend a depth D1 below a top surface of the dielectric layer 40 that is in the range of about 1 nm to about 3 nm, though other depths are possible. In other embodiments, the recesses 54 do not extend below a top surface of the dielectric layer 40. In some embodiments, the recesses 54 expose top surfaces and/or sidewall surfaces of conductive feature(s) 42. The recesses 54 may have sidewalls that are angled, tapered, substantially vertical, or the like.

After forming the recesses 54, the remaining portions of the barrier layer 44, the conductive layer 46 form conductive features 56. For example, FIG. 4 shows four conductive features 56A, 56B, 56C, and 56D, each of which comprise a portion of barrier layer 44 and an overlying portion of conductive layer 46. The conductive features 56 may be conductive lines, vias, or the like. In some embodiments, the recesses 54 have a width Wo that is in the range of about 8 nm to about 20 nm, though other widths are possible. In some embodiments, the conductive features 56 have a width W1 in the range of about 8 nm to about 20 nm, though other widths are possible. Some conductive features 56 may be formed on underlying conductive features 42, an example of which is conductive feature 56C in FIG. 4. In some embodiments, a width W1 of a conductive feature 56 may be smaller than a width of an underlying conductive feature 42. In such embodiments, sidewalls of the underlying conductive feature 42 may protrude beyond sidewalls of the conductive feature 56, and top surfaces of the underlying conductive feature 42 may be exposed by the recesses 54. In other embodiments, a width W1 of a conductive feature 56 may be about the same as or less than a width of an underlying conductive feature 42. The conductive features 56 described above are examples, and other conductive features 56 or other steps for forming the recesses 54 that define the conductive features 56 are possible. In some cases, forming conductive features by etching a conductive layer can avoid problems associated with other techniques, such as metal fill seams or voids associated with damascene processes. In this manner, the reliability or yield of conductive features may be improved.

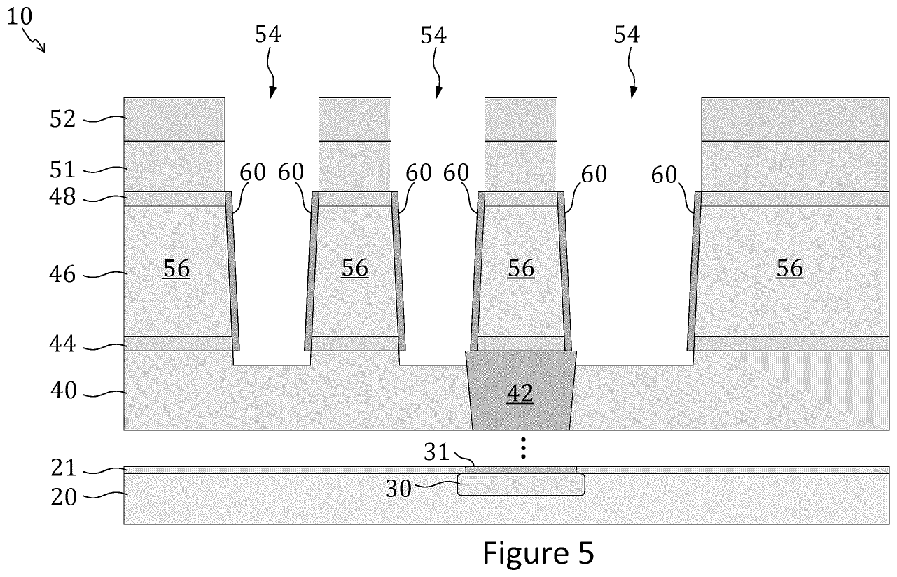

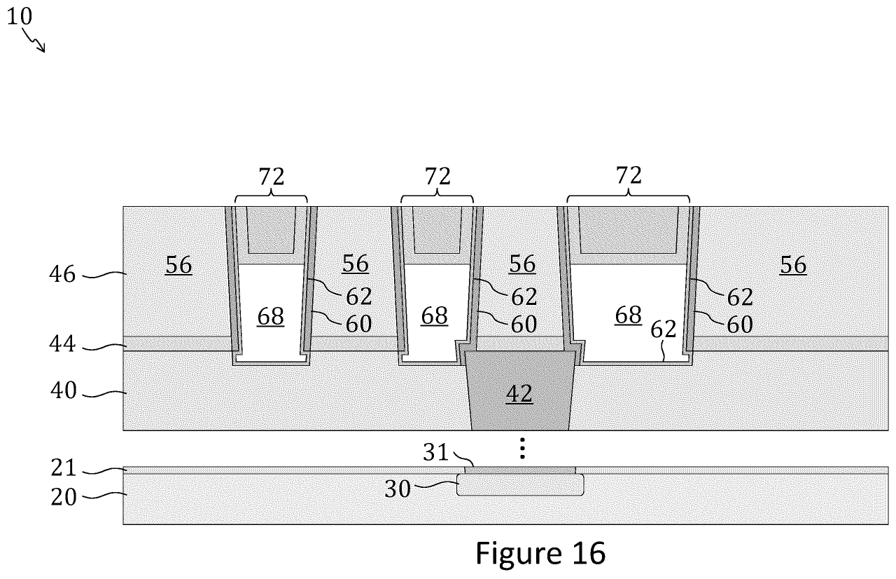

In FIG. 5, a capping material 60 is selectively deposited on sidewalls of the conductive features 56, in accordance with some embodiments. The capping material 60 may be selectively deposited on exposed surfaces of metal-containing materials without being deposited on exposed surfaces of dielectric materials. For example, the capping material 60 may be selectively deposited on exposed surfaces of the barrier layer 48, the conductive layer 46, and the barrier layer 44, and not significantly deposited on exposed surfaces of the dielectric layer 40, hard mask layer 51, and hard mask layer 52. In other words, the dielectric layer 40 is free of the capping material 60. In some embodiments, the capping material 60 is also selectively deposited on exposed surfaces of the conductive feature 42 (see FIG. 16).

In some cases, exposed surfaces of the conductive layer 46 can deform when exposed to high temperatures, which can cause performance degradation and yield loss of the conductive features 56. For example, exposed surfaces of ruthenium may deform at temperatures above 400° C. due to atomic agglomeration. By covering the sidewalls of the conductive layer 46 with the capping material 60, high-temperature deformation of the conductive layer 46 can be reduced or prevented. Further, the capping material 60 can protect the sidewalls of the conductive features 56 during subsequent processing steps. In this manner, the use of capping material 60 as described herein can allow for conductive features having sidewalls with reduced roughness and/or improved planarity.

In some embodiments, the capping material 60 may be a material that can be selectively deposited at a temperature that does not cause significant deformation of the conductive layer 46. For example, for embodiments in which the conductive layer 46 is ruthenium, the capping material 60 may be a material that can be selectively deposited at a temperature less than about 400° C. For example, in some embodiments, the capping material 60 may comprise molybdenum, cobalt, graphene, or the like, which can be selectively deposited at a temperature less than about 400° C. The capping material 60 may be deposited using a suitable technique, such as CVD, PECVD, ALD, or the like. For example, molybdenum may be selectively deposited using precursor of molybdenum (V) chloride (MoCl₅) or the like at a temperature in the range of about 275° C. to about 400° C. Cobalt may be selectively deposited using, for example, cyclopentadienylcobalt dicarbonyl ((C₅H₅)Co(CO)₂), bis(cyclopentadienyl)cobalt(II) (Co(C₅H₅)₂), or the like at a temperature in the range of about 150° C. to about 350° C. Graphene may be selectively deposited using PECVD at a temperature in the range of about 250° C. to about 400° C. Other materials, precursors, or temperatures are possible. In some embodiments, the capping material 60 is deposited to a thickness in the range of about 20 Å to about 40 Å, though other thicknesses are possible.

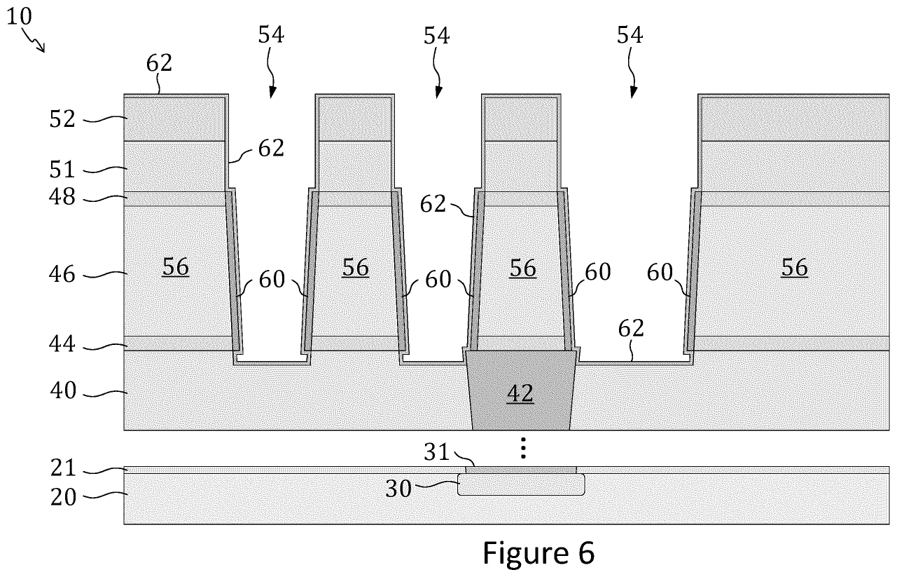

In FIG. 6, a liner 62 is conformally deposited in the recesses 54, in accordance with some embodiments. The liner 62 may be conformally deposited on exposed surfaces of the capping material 60 and the dielectric layer 40, for example. In some cases, the liner 62 may also be conformally deposited on exposed surfaces of the conductive feature 42, the hard mask layer 51, and/or the hard mask layer 52. The liner 62 may comprise one or more materials such as silicon carbide, silicon carbonitride, silicon oxycarbide, silicon nitride, the like, or combinations thereof. The liner 62 may be formed using a conformal deposition process such as ALD, CVD, PECVD, or the like. For example, in some embodiments, the liner 62 is a layer of silicon oxycarbide that is conformally deposited using PECVD, though other materials are possible. In some cases, the liner 62 is deposited at temperature greater than about 400° C., and the capping material 60 protects the conductive layer 46 from deformation during the deposition.

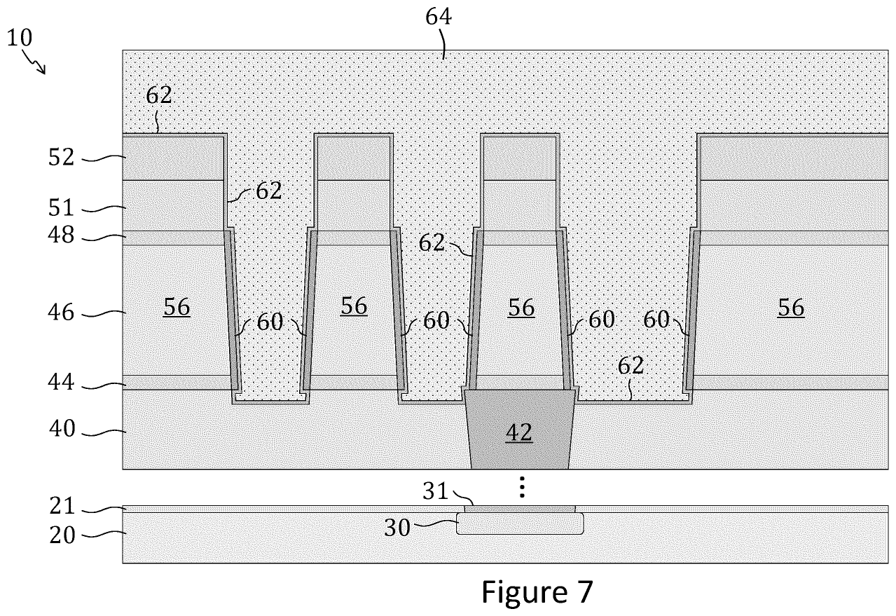

In FIG. 7, a sacrificial material 64 is deposited over the liner 62, in accordance with some embodiments. The sacrificial material 64 may partially fill, completely fill, or overfill the recesses 54. In some embodiments, the sacrificial material 64 comprises a polymer, such as a CxHy polymer or another type of polymer. The sacrificial material 64 may be deposited using a suitable technique, such as CVD, PECVD, spin-on, or the like.

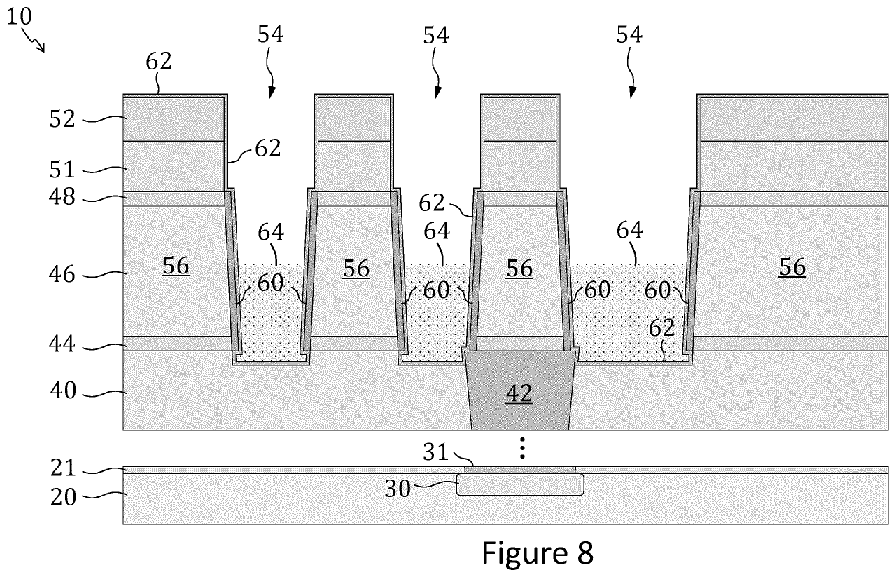

In FIG. 8, an etch-back process is performed on the sacrificial material 64, in accordance with some embodiments. The etch-back process may include a wet etching process or a dry etching process, which may be anisotropic. In some embodiments, the etch-back process includes a timed etch. The etch-back process removes portions of the sacrificial material 64 between the recesses 54 (if any) and removes upper portions of the sacrificial material 64 within the recesses 54. For example, the etch-back process may remove portions of the sacrificial material 64 that are adjacent upper sidewalls of the capping material 60 or upper sidewalls of the conductive features 56. After performing the etch-back process, the remaining portions of the sacrificial material 64 partially fill the recesses 54. In some embodiments, a top surface of the remaining portions of the sacrificial material 64 has a height that is between a height of a bottom surface of the conductive layer 46 and a height of a top surface of the conductive layer 46. In some embodiments, the remaining portions of the sacrificial material 64 has a thickness in the range of about 12 nm to about 20 nm, though other thicknesses are possible. FIG. 8 shows the remaining portions of the sacrificial material 64 as having planar top surfaces, but in other cases the top surfaces may be convex, concave, or irregular.

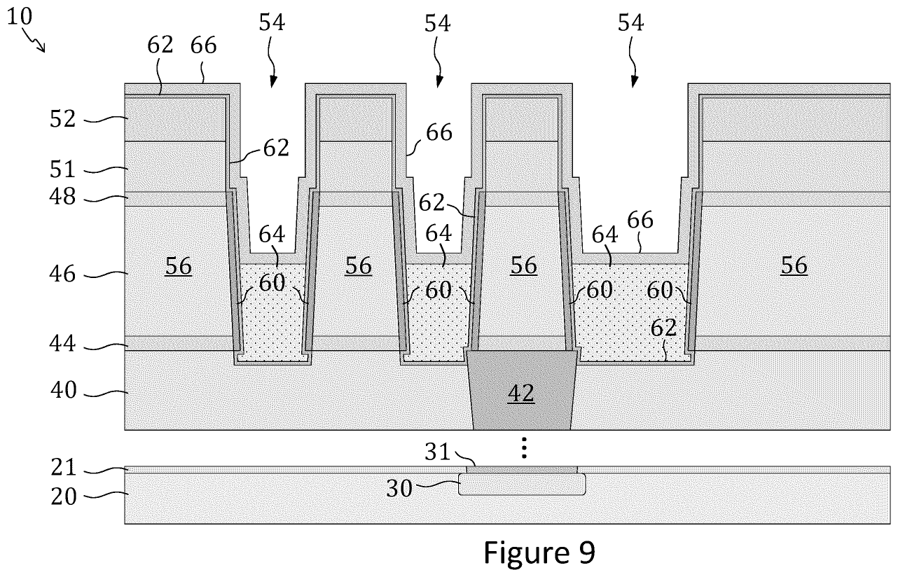

In FIG. 9, a sustain layer 66 is conformally deposited over the sacrificial material 64, in accordance with some embodiments. The sustain layer 66 may be conformally deposited on surfaces within the recesses 54 and between the recesses 54. For example, the sustain layer 66 may be conformally deposited on exposed surfaces of the liner 62 and the sacrificial material 64. In some embodiments, the sustain layer 66 comprises a dielectric material such as silicon oxide or the like that is deposited using a suitable technique such as PECVD or the like. Other materials or techniques are possible. In some embodiments, the sustain layer 66 has a thickness in the range of about 1 nm to about 3 nm, though other thicknesses are possible.

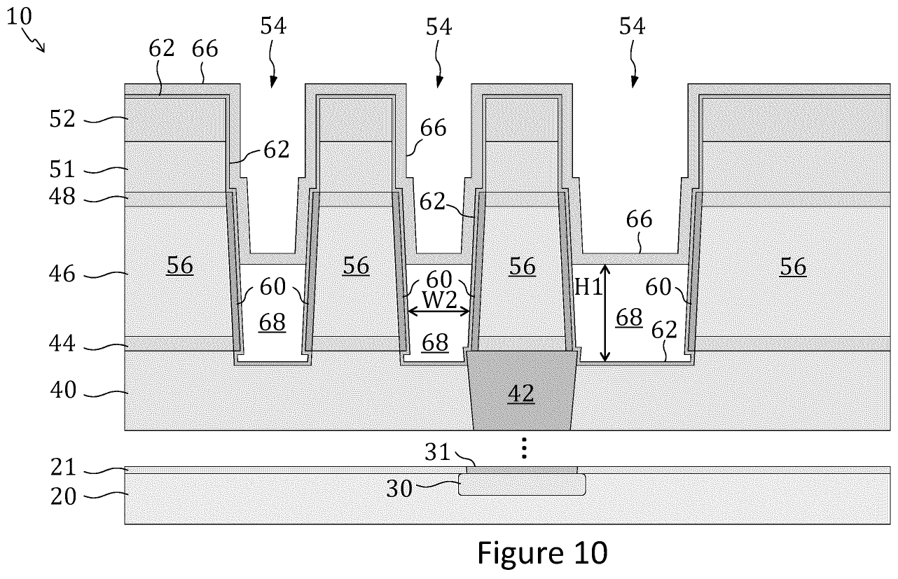

In FIG. 10, a thermal process is performed to remove the sacrificial material 64 and form air gaps 68, in accordance with some embodiments. The thermal process removes the sacrificial material 64 without removing the sustain layer 66, leaving air gaps 68 underneath the sustain layer 66. In some embodiments, the thermal process comprises an annealing process, a baking process, a UV heating process, or the like. In some embodiments, the thermal process is performed at a temperature in the range of about 300° C. to about 500° C., though other temperatures are possible.

After performing the thermal process, the sustain layer 66 remains extending between sidewalls of the conductive features 56, and thus may at least partially seal top regions of the air gaps 68. In this manner, the air gaps 68 are at least partially surrounded by surfaces of the liner 62 and bottom surfaces of the sustain layer 66. FIG. 10 shows the sustain layer 66 over the air gaps 68 as being substantially flat, but in other cases the sustain layer 66 over the air gaps 68 may have a curved profile, such as a convex or concave profile. The air gaps 68 may extend below a top surface of the dielectric layer 40, extend over a top surface of the conductive feature 42, and/or extend along a sidewall surface of the conductive feature 42, in some embodiments. The air gaps 68 may have a height H1 that is in the range of about 15 nm to about 20 nm or a width W2 that is in the range of about 6 nm to about 15 nm, though other dimensions are possible. In this manner, air gaps 68 are formed between neighboring conductive features 56. Forming air gaps 68 between conductive features 56 can improve isolation between conductive features 56 and reduce capacitances between conductive features 56, which can improve device performance.

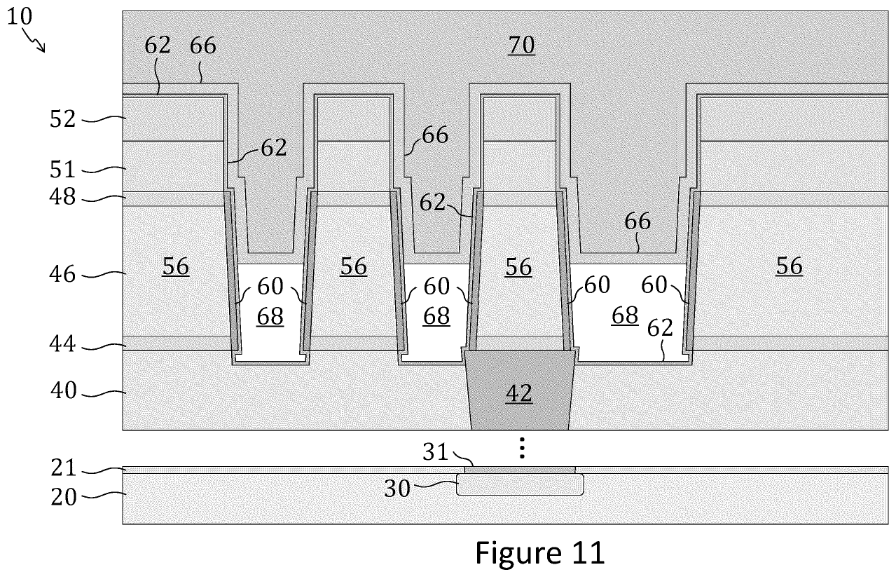

In FIG. 11, a dielectric fill material 70 is deposited over the sustain layer 66, in accordance with some embodiments. The dielectric fill material 70 may partially fill, completely fill, or overfill the recesses 54. The sustain layer 66 blocks the dielectric fill material 70 from depositing in the air gaps 68, and thus the air gaps 68 remain after depositing the dielectric fill material 70. The dielectric fill material 70 may be a material such as silicon oxide, silicon nitride, silicon oxynitride, or the like, and may be deposited using a suitable technique such as CVD, PECVD, PVD, ALD, or the like.

In FIG. 12, a planarization process is performed on the structure, in accordance with some embodiments. The planarization process may include, for example, a Chemical-Mechanical Polish (CMP) process, a grinding process, or the like. The planarization process may remove the hard mask layer 51, the hard mask layer 52, and the barrier layer 48. Accordingly, the planarization process may also remove upper portions of the dielectric fill material 70, the sustain layer 66, the liner 62, and the capping material 60. In some cases, the planarization process may also remove upper portions of the conductive layer 46. After performing the planarization process, top surfaces of the conductive layer 46, capping material 60, liner 62, sustain layer 66, and/or dielectric fill material 70 may be substantially level or coplanar.

After performing the planarization process, remaining portions of the sustain layer 66 and dielectric fill material 70 form seals 72 that at least partially seal the air gaps 68. The seals 72 may have a height H2 that is in the range of about 5 nm to about 10 nm, though other heights are possible. In some embodiments, the height H2 may be between about 20% and about 100% of the height H1, though other heights are possible. In some cases, forming relatively smaller seals 72 (e.g., relatively larger air gaps 68) may allow for smaller parasitic capacitances between adjacent conductive features 56.

After performing the planarization process, remaining portions of the barrier layer 44 and conductive layer 46 form the conductive features 56, in accordance with some embodiments. The conductive features 56 may have a height H3 in the range of about 12 nm to about 20 nm, though other heights are possible. As shown in FIG. 12, the height H3 may be less than the sum of the height H1 and the height H2, in some embodiments.

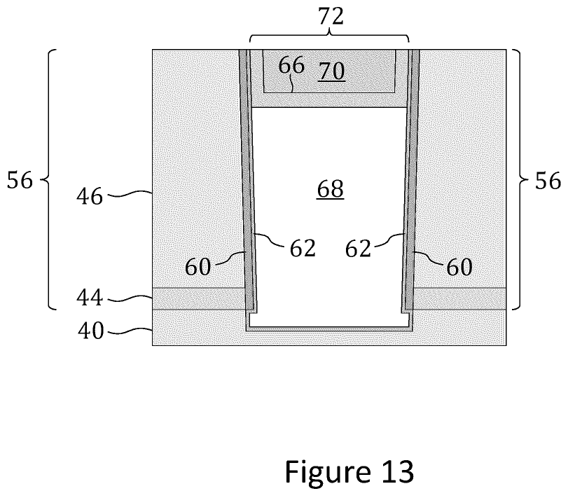

FIG. 13 illustrates a magnified view of a region around an air gap 68, in accordance with some embodiments. The region shown in FIG. 13 may be similar to portions of the structure shown in FIG. 12. As shown in FIG. 13, the air gaps 68 may extend underneath the capping material 60, in some embodiments. In other words, a region an air gap 68 adjacent the dielectric layer 40 may have a greater width than a region of the air gap 68 adjacent the conductive features 56. The conductive features 56 may be separated from the air gaps 68 by the capping material 60 and the liner 62. The conductive features 56 may be separated from the seals 72 by the capping material 60 and the liner 62. The air gaps 68 may have angled sidewalls, tapered sidewalls, vertical sidewalls, or sidewalls of a different profile shape. Bottom surfaces of the air gaps 68 may be flat, concave, convex, or irregular.

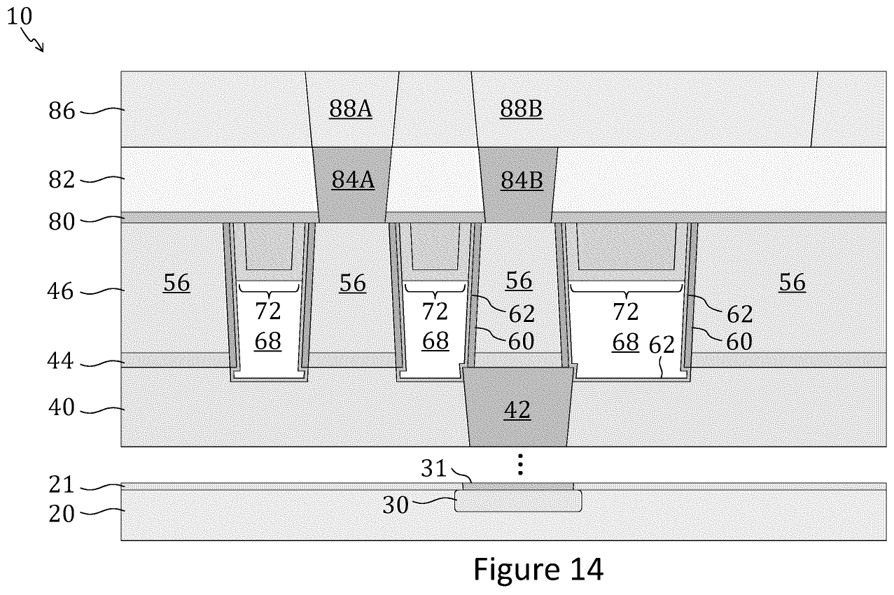

After forming the conductive features 56, additional processing steps may be performed. For example, additional conductive features may be formed over the conductive features 56 using processing steps similar to those described for the conductive features 56. As another example, FIG. 14 illustrates the formation of additional vias 84A-B and conductive features 88A-B over the conductive features 56, in accordance with some embodiments. The vias 84A-B and conductive features 88A-B are intended as a non-limiting example, and other vias, conductive lines, or conductive features may be formed using other processes.

In FIG. 14, a dielectric layer 82 is deposited over the seals 72 and the conductive features 56. In some embodiments, the dielectric layer 82 is a flowable film formed by a flowable CVD method. In some embodiments, the dielectric layer 82 may be a material similar to that of the dielectric layer 21 or the dielectric layer 40, and may be formed in a similar manner. For example, the dielectric layer 112 may be formed of a dielectric material such as an oxide, PSG, BSG, BPSG, USG, or the like, and may be deposited by any suitable method, such as CVD or PECVD. In some embodiments, an optional etch stop layer 80 is formed before depositing the dielectric layer 82 The etch stop layer 80 may comprise a dielectric material, such as silicon nitride, silicon oxynitride, silicon oxycarbide, or the like, and may be deposited using any suitable technique, such as CVD, PECVD, PVD, ALD, or the like.

Openings (not separately illustrated) may then be formed extending through the dielectric layer 82 and the etch stop layer 80 to expose conductive features 56. The openings may be formed using suitable photolithography and etching processes. For example, a photoresist may be formed over the dielectric layer 82 and patterned. The photoresist can be formed by using, for example, a spin-on technique and can be patterned using acceptable photolithography techniques. One or more suitable etch processes may be performed using the patterned photoresist as an etch mask, forming the openings. The one or more etch processes may include wet etching processes and/or dry etching processes.

A conductive material is then deposited in the openings to form vias 84A-B. The conductive material may be similar to those described previously for the conductive feature 42 or the conductive layer 46. In some cases, the vias 84A-B and the conductive feature 42 may comprise the same conductive material. For example, in some embodiments the conductive material comprises molybdenum, though other materials are possible. The conductive material may be deposited using a suitable technique, such as CVD, PECVD, ALD, plating, or the like. In some embodiments, a planarization process (e.g., a CMP process or the like) may be performed such that top surfaces of the dielectric layer 82 and the vias 84A-B are level.

A dielectric layer 86 may then be formed over the dielectric layer 82 and the vias 84A-B. The dielectric layer 86 may be a material similar to those described for the dielectric layer 82, and may be formed using similar techniques. Openings (not separately illustrated) may then be formed in the dielectric layer 86, some of which may expose underlying conductive features such as the vias 84A-B. Conductive material may then be deposited into the openings to form the conductive features 88A-B. The conductive material may comprise one or more materials similar to those described previously for the vias 84A-B or the conductive features 42. In some embodiments, the conductive features 88A-B may be formed of different materials than the underlying vias 84A-B. For example, in some embodiments, the vias 84A-B may comprise molybdenum and the conductive features 88A-B may comprise copper, though other materials are possible. The conductive features 88 may include vias, such as conductive feature 88A, conductive lines, such as conductive feature 88B, or the like.

The vias 84A-B and conductive features 88A-B are an example, and other conductive features may be formed over the conductive features 56 in other embodiments. For example, the vias 84A-B and conductive features 88A-B may be formed simultaneously of the same conductive material in other embodiments. The conductive features may comprise metallization patterns, redistribution layers, or the like, and may be formed using any suitable technique, such as damascene, dual damascene, or the like. In some cases, the conductive features may be formed using a “barrier-less” process.

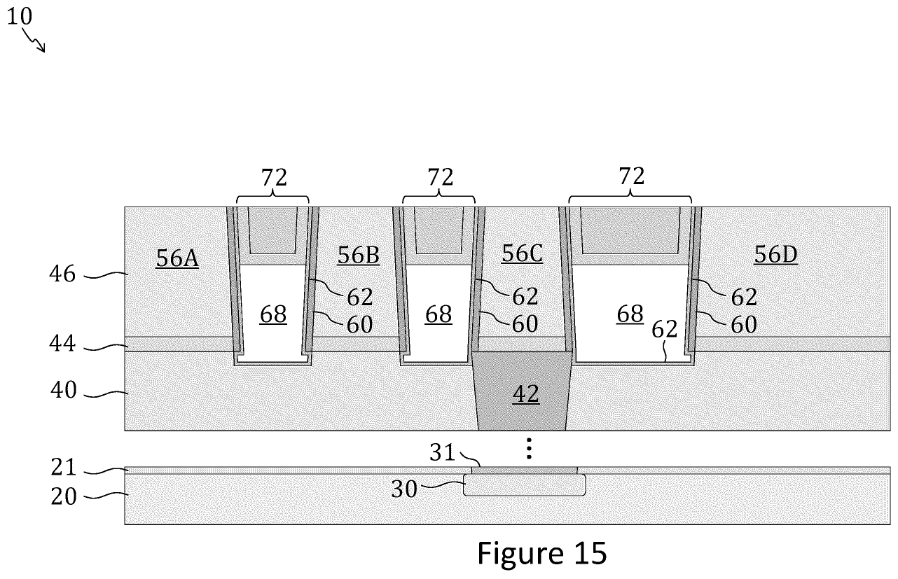

FIG. 15 illustrates a cross-sectional view of conductive features 56A-D, in accordance with some embodiments. The conductive features 56A-D are similar to the conductive features 56 of FIG. 12, except that the liner 62 is not formed on a top surface of the underlying conductive feature 42. As shown in FIG. 15, the conductive feature 56C may have a width such that the capping material 60 covers top surfaces of the conductive feature 42, blocking deposition of the liner 62 on the top surfaces of the conductive feature 42. In other embodiments, the conductive feature 56C may have a width such that the capping material 60 and/or the barrier layer 44 protrudes laterally from (e.g., overhangs) the conductive feature 42.

FIG. 16 illustrates a cross-sectional view of conductive features 56, in accordance with some embodiments. The conductive features 56 are similar to the conductive features 56 of FIG. 12, except that the capping material 60 is selectively deposited on surfaces of the underlying conductive feature 42 in addition to surfaces of the barrier layer 44 and the conductive layer 46. For example, the capping material 60 may selectively deposit on top surfaces and/or sidewall surfaces of the conductive layer 46. Because the capping material 60 covers these surfaces of the conductive feature 42, the conductive feature 42 is separated from the liner 62 by the capping material 60. Accordingly, the conductive feature 42 is separated from air gaps 68 by the capping material 60 and the liner 62. In other embodiments, top surfaces of the conductive feature 42 may be covered by the barrier layer 44, and thus the capping material 60 may be deposited on sidewalls of the conductive feature 42 only.

Embodiments described herein may achieve advantages. Selectively depositing a capping layer on sidewalls of conductive features can protect the conductive features from some temperature-related effects. For example, the capping layer can reduce or prevent deformation of the sidewalls of the conductive features during process steps that use higher temperatures. This can allow for improved formation of conductive features using materials that are less stable at higher temperatures. In some cases, these materials may have a smaller resistance, such as ruthenium, and thus the embodiments described herein can allow for the formation of conductive features having smaller resistance and improved thermal stability. By reducing sidewall deformation, the line width roughness of conductive features may be reduced. Reducing sidewall deformation in this manner can also allow for the formation of smaller conductive features, conductive features having a smaller pitch, and devices of higher density. The embodiments described herein can also allow for reduced variation, improved reliability, and improved yield. Further, by forming air gaps between conductive features, parasitic capacitances between the conductive features may be reduced, which can improve device efficiency, speed, and performance.

In some embodiments of the present disclosure, a method includes forming a conductive layer over a first dielectric layer; etching a recess in the conductive layer, wherein the recess exposes a top surface of the first dielectric layer; selectively depositing a capping layer on exposed sidewalls of the conductive layer within the recess; depositing a liner on the capping layer; forming a sacrificial material in the recess; and forming a second dielectric layer on the sacrificial material and on sidewalls of the recess; and after forming the second dielectric layer, performing a thermal process to remove the sacrificial material. In an embodiment, the method includes forming a first barrier layer between the conductive layer and the first dielectric layer. In an embodiment, the method includes forming a second barrier layer on a top surface of the conductive layer. In an embodiment, forming the sacrificial material includes filling the recess with the sacrificial material and performing an etch-back process to remove upper portions of the sacrificial material. In an embodiment, the liner physically contacts a top surface of first dielectric layer. In an embodiment, performing the thermal process to remove the sacrificial material forms an air gap underneath the second dielectric layer. In an embodiment, the method includes forming a third dielectric layer on the second dielectric layer after performing the thermal process, wherein the regions underneath the second dielectric layer remain free of the third dielectric layer. In an embodiment, the method includes performing a planarization process to remove upper portions of the second dielectric layer, the capping layer, and the liner.

In some embodiments of the present disclosure, a method includes depositing a first dielectric material over a substrate; depositing a first barrier layer over the first dielectric material; depositing a conductive material over the first barrier layer; etching recesses extending through the conductive material and the first barrier layer; selectively depositing a protective material on exposed surfaces of the conductive material and the first barrier layer, wherein the first dielectric material is free of the protective material; and depositing a liner layer on the protective material and the first dielectric material. In an embodiment, the method includes filling the recesses with a sacrificial material; removing upper portions of the sacrificial material to expose the liner layer within the recesses; depositing a second dielectric material on the sacrificial material; and removing the remaining portions of the sacrificial material to form air gaps in the recesses. In an embodiment, a top surface of the conductive material is higher than the air gaps. In an embodiment, at least one recess exposes a conductive feature underlying the first dielectric material. In an embodiment, the recesses extend lower than a top surface of the first dielectric material. In an embodiment, the conductive material is ruthenium. In an embodiment, the protective material is deposited to a thickness in the range of 20 Å to 40 Å.

In some embodiments of the present disclosure, a structure includes a first conductive feature and a second conductive feature over a first dielectric layer, wherein the first conductive feature and the second conductive feature each include a barrier layer over the first dielectric layer; a conductive layer over the barrier layer; and a capping layer on sidewalls of the barrier layer and the conductive layer; a liner layer extending on a sidewall of the first conductive feature, a sidewall of the second conductive feature, and a top surface of the first dielectric layer; and a second dielectric layer extending from the liner layer on the sidewall of the first conductive feature to the liner layer on the sidewall of the second conductive feature, wherein the second dielectric layer extends over an air gap. In an embodiment, the air gap extends underneath the capping layer of the first conductive feature. In an embodiment, the structure includes a third conductive feature within the first dielectric layer, wherein the barrier layer of the first conductive feature physically contacts the third conductive feature. In an embodiment, the conductive layer and the third conductive feature are different conductive materials. In an embodiment, the capping layer includes one of molybdenum, cobalt, or graphene.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure comprising:
a conductive feature over a dielectric layer;
a conductive layer covering a sidewall of the conductive feature;
an air gap over the dielectric layer and along the sidewall of the conductive feature, wherein the air gap is separated from the conductive feature by the conductive layer; and
a seal over the air gap and along the sidewall of the conductive feature, wherein the seal is separated from the conductive feature by the conductive layer.

2. The structure of claim 1, wherein a vertical dimension of the conductive layer is greater than a vertical dimension of the conductive feature.

3. The structure of claim 1, wherein the dielectric layer is free of the conductive layer.

4. The structure of claim 1 further comprising a liner layer over the conductive layer.

5. The structure of claim 1, wherein the air gap extends below a top surface of the dielectric layer.

6. The structure of claim 1 further comprising a barrier layer between the conductive feature and the dielectric layer.

7. The structure of claim 1, wherein the conductive feature and the conductive layer are different conductive materials.

8. The structure of claim 1, wherein the air gap extends underneath the conductive layer.

9. A structure comprising:
a conductive feature in an insulating layer;
a first conductive material on a top surface of the conductive feature;
a second conductive material on a top surface of the first conductive material;
a third conductive material on a sidewall of the first conductive material and a sidewall of the second conductive material; and
an air gap adjacent to the third conductive material and a sidewall of the conductive feature.

10. The structure of claim 9, wherein a bottom portion of the air gap is below a top surface of the conductive feature.

11. The structure of claim 9, wherein the third conductive material is on a top surface of the conductive feature.

12. The structure of claim 9, wherein the third conductive material is on a sidewall of the conductive feature.

13. The structure of claim 9, wherein the conductive feature and the second conductive material are different conductive materials.

14. The structure of claim 9, wherein the first conductive material is titanium nitride.

15. The structure of claim 9, wherein the second conductive material is ruthenium.

16. The structure of claim 9, wherein the third conductive material is molybdenum.

17. A method comprising:
forming a first conductive layer over a first dielectric layer;
etching a first recess and a second recess in the first conductive layer to form a conductive feature between the first recess and the second recess;
forming a second conductive layer on sidewalls of the conductive feature using a selective deposition process;
forming a second dielectric layer that seals the first recess to form a first air gap in the first recess and that seals the second recess to form a second air gap in the second recess.

18. The method of claim 17 further comprising planarizing the second dielectric layer such that top surfaces of the first conductive layer and the second dielectric layer are level.

19. The method of claim 17, wherein the second conductive layer comprises cobalt.

20. The method of claim 17 further comprising:
depositing a sacrificial material into the first recess and the second recess, wherein the second dielectric layer is formed on the sacrificial material; and
after forming the second dielectric layer, removing the sacrificial material.
